(19) United States
(12) Patent Application Publication
(10) Pub. No.: US 2004/0066623 A1
(43) Pub. Date: Apr. 8, 2004

(54) STRUCTURE OF A HEAT DISSIPATION DEVICE FOR COMPUTERS

(76) Inventor: Cheng-Kuo Lu, Taipei (TW)

Correspondence Address: Cheng-Kuo Lu, PO Box 82-144, TAIPEI, TW

(21) Appl. No.: 10/265,231

(22) Filed: Oct. 7, 2002

(51) Int. Cl. H05K 7/20; F28F 7/00

(52) U.S. Cl. 361/697; 165/80.3

(57) ABSTRACT

A structure of a heat dissipation device for a computer is disclosed. The heat dissipation device comprises a heat dissipation body, a plurality of metallic foil-like branching plates, a plurality of partitioning plates, characterized in that the heat dissipation body is a frame structure having an interior cavity and having a planar contacting bottom face; the foil-like branching plates are made from thin plate body with continuing bends; and each of the partitioning plates has a planar bottom face and a heat conductive contacting edge at the two lateral sides thereof; thereby the interior cavity is mounted with the partitioning plates, branching plates such that the branching plates and the partitioning plates are stacked in subsequent layers and under the downward pressing of the heat dissipation body and the heating by a high temperature furnace, each branching plates, the partitioning plates and the heat dissipation body are melted to form as a unit, providing quick dissipation of heat.

### BACKGROUND OF THE INVENTION

(A) Field of Invention

This invention relates to a structure of a heat dissipation device for computers, and more particularly to a heat dissipation device having a large surface for heat dissipation, which provides excellent heat dissipation for CPU of computer.

(B) Description of the Prior Art

Conventional heat dissipation device for CPU is made from aluminum material and is extruded as an integral unit. The bottom of the device is provided with a planar contacting bottom plate and the top thereof is provided with a plurality of heat dissipation plates. The drawbacks of this conventional device are as follows:

The plates are of limited sizes and thickness (about more than I mm), and the length of the dissipation plate cannot be too long to allow fabrication. As a result there are a plurality of gaps between the plates and the total number of dissipation plates is limited. As such the heat dissipation efficiency of the conventional heat dissipation device is low.

Referring to FIG. 9, there is shown a conventional heat dissipation device with hollow heat dissipation plates, hollow branching plate Q having a thin continuing bends as left dissipation face B, right heat dissipation face C and continuing bending bottom flat face D. In the fabrication process, the bottom planar face D of the branching plate A is welded or mounted with heat dissipation agent to the heat dissipation body 1 to allow heat energy absorption and dissipation. The branching plate A is made from thin plate, and therefore the number of plate distribution at unit area is large and therefore the surface area for heat dissipation is increased. Further, the gaps between the branching plates allow the passage of chilled air and therefore the rate of heat dissipation is rapid.

However, the quality of heat dissipation efficiency depends on the planar contact of the planar face D and the contacting surface of the heat dissipation body 1. If the planar contact is not fully in contact, then the heat dissipation efficiency will be affected. If the contact is a full contact, then excellent heat dissipation is obtained.

Accordingly, it is an object of the present invention to provide a structure of a heat dissipation device for computer, which overcomes the above-mentioned drawbacks.

### SUMMARY OF THE INVENTION

The present invention is directed to the provision of a structure of a heat dissipation device for a computer having a heat dissipation body, a plurality of metallic foil-like branching plates, a plurality of partitioning plates, characterized in that the heat dissipation body is a frame structure having an interior cavity and having a planar contacting bottom face; the foil-like branching plates are made from thin plate body with continuing bends; and each of the partitioning plates has a planar bottom face and a heat conductive contacting edge at the two lateral sides thereof; thereby the interior cavity is mounted with the partitioning plates, branching plates such that the branching plates and the partitioning plates are stacked in subsequent layers and under the downward pressing of the heat dissipation body and the heating by a high temperature furnace, each branching plates, the partitioning plates and the heat dissipation body are melted to form as a unit, providing quick dissipation of heat.

Yet another object of the present invention is to provide a structure of a heat dissipation device for computer, wherein the device has a larger heat dissipation surface area, which provides excellent heat dissipation.

A further object of the present invention is to provide a structure of a heat dissipation device for computer, wherein the connections of the plates are mounted using heat dissipation agents so as to provide excellent heat dissipation.

Yet another object of the present invention is to provide a structure of a heat dissipation device for computer, wherein the branching plate is provided with conductive slots for the passage of cool air, providing rapid heat dissipation.

The foregoing object and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### DESCRIPTION OF THE DRAWINGS

In the accompanying drawings:

FIG. 1 is a perspective view of a first preferred embodiment in accordance with the present invention.

FIG. 2 is a perspective exploded view of a first preferred embodiment in accordance with the present invention.

FIG. 3 is the front view of a first preferred embodiment of the present invention.

FIG. 4 is a partial enlarged view of a first preferred embodiment in accordance with the present invention.

FIG. 5 is a sectional view of FIG. 4 in accordance with the present invention.

FIG. 6 is a perspective exploded view of a second preferred embodiment in accordance with the present invention.

FIG. 7 is a perspective view of a third preferred embodiment in accordance with the present invention.

FIG. 8 is a perspective view of forth preferred embodiment in accordance with the present invention.

FIG. 9 is a sectional view of a conventional heat dissipation plate.

### DETAILED DESCRIPTION OF THE PREFERRED EMBODIMENT

The following descriptions are of exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

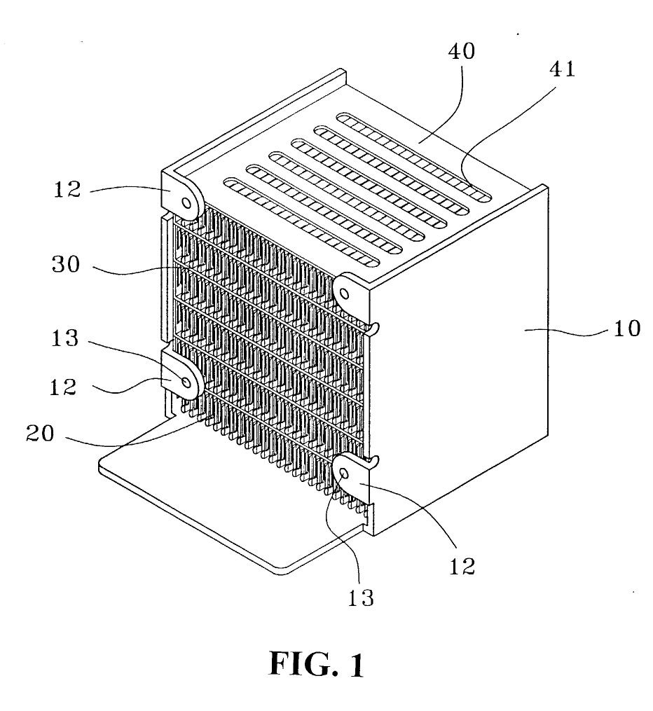

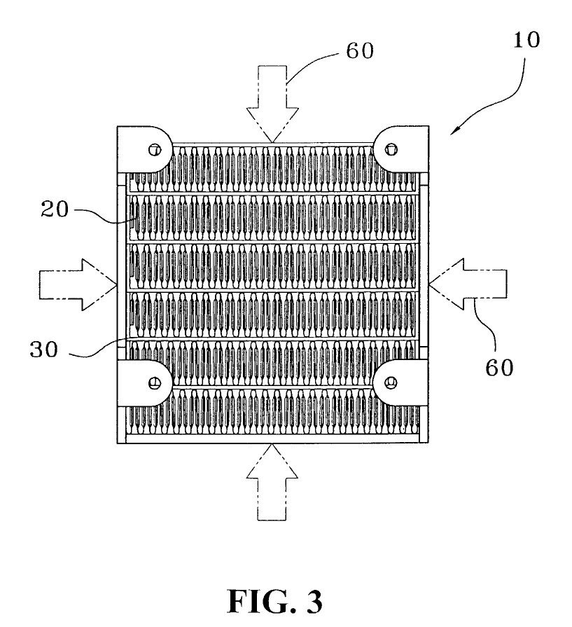

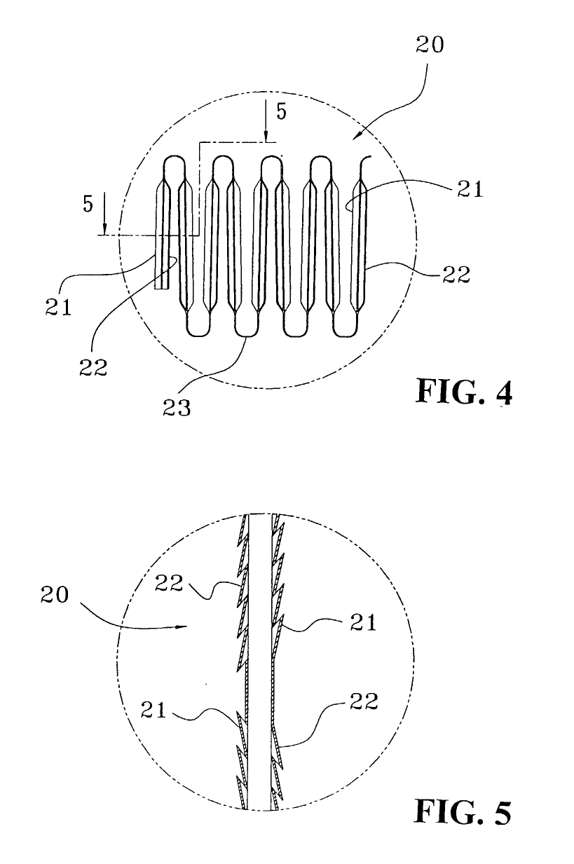

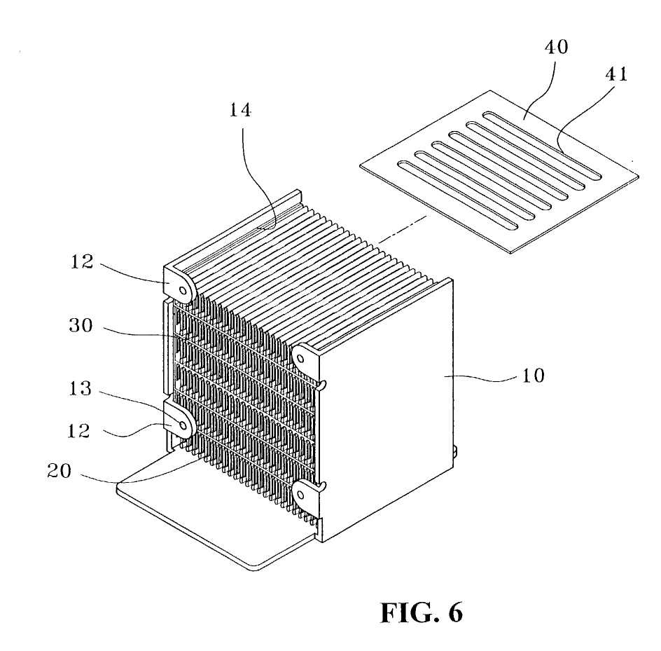

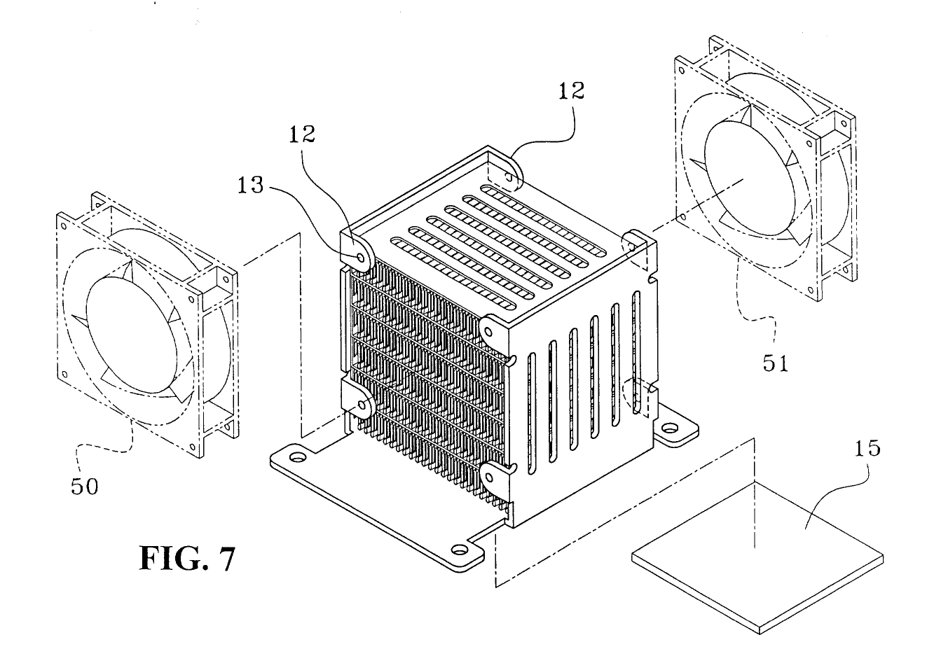

With reference the drawings, in particular to FIG. 1, a preferred embodiment of the invention is illustrated and FIGS. 1 and 3 show a structure of heat dissipation device for CPU of computer comprising a heat dissipation body 10, a plurality of metallic foil-like branching plates 20, a plurality of partitioning plates 30, and a covering plate 40, wherein the heat dissipation body 10 is a U-shaped frame structure having an interior cavity 11 and one side of the heat dissipation body 10 or the front and rear corner of the body 10 is provided with protruding plate 12 having screw hole 13 for the mounting of a front venting fan 50 or a rear venting fan 51 (referring to FIG. 7), and the rear end of the heat dissipation body is locked with the front venting fan 51 to provide raid conduction of chilled air to provide excellent cooling of temperature.

The plurality of the foil-like branching plates 20 are made from thin plate body with continuing bends and of multiple layers. The branching plates 20 are provided with a plurality of right side slanting conductive slots 21 and the left-side slanting conductive slots 22. The two types of conductive slots are arranged in alternate positive and reverse direction arrangement (as shown in FIG. 5).

The plurality of the he partitioning plates 30 are plate bodies which have a planar bottom face 31 and a heat conductive contacting edge 32 at the two lateral sides thereof, and the wall of the edge 32 is provided with venting slot 33. The covering plate 40 is a planar plate body having through hole 41.

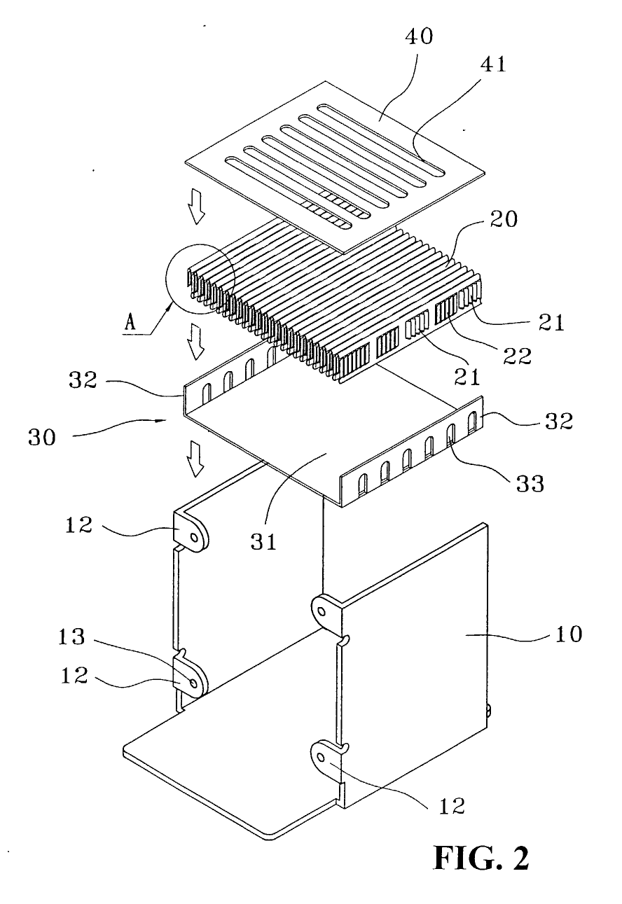

As shown in FIG. 2, in the fabrication process, the branching plate 20 and the partitioning plate 30 are stacked layers by layers such that the bending end 23 of the branching plate 20 urges the planar bottom plate 31 of the partitioning plate 30. By means of the utmost end terminal urging with the covering plate 40 being inserted into the heat dissipation body 10, the branching plates 20 are mounted within the interior cavity 11 of the U-shaped frame.

Referring to FIG. 3, when all the components are installed as described above the external of the dissipation body 10 is pressed with an external force 60 at is placed under a high temperature furnace for heating at a specific temperature at a specific time such that the bending end 23 of the branching plate 20 and the planar bottom face 31 of the partitioning plate are fused to form an integral unit. At the same time, the individual end edges 32 of the individual partitioning plate 30 are fused with the heat dissipation body 10 as one unit, so that a heat dissipation device having thin foil-like branching plates is obtained. In accordance with the present invention, the total surface area for heat dissipation is larger than the conventional heat dissipation device.

In accordance with the present invention, the branching plates 20 are made from thin foil, and preferably made of aluminum material, and the thickness is reduced to 0.05 mm to 1 mm. Due to the size of the thickness is small, larger heat dissipation efficiency is obtained and the rate of dissipation is rapid. The two lateral end of the U-shaped frame are provided with engaging slot 14 for the engaging of the upper layer covering plate 40 so that the branching plates 20, the partitioning plates 30 within the cavity 11 are more closely urged together. Under high temperature fusion, the plates are fused to form one unit, providing excellent heat dissipation.

Referring to FIG. 7, in order to provide excellent heat dissipation for the entire branching plates 20, the front edge protruding plate 12 is mounted with the front venting fan 50 and the rear lateral side is mounted with the rear venting fan 51. Therefore the front and rear vertical directions of the branching plates 20 are in good ventilation. Hence the chilled air flowing across the branching plates 20 provides excellent heat dissipation.

The right-side slanting direction slot 21 and the left-side slanting direction slot 22 are mounted in alternate arrangement such that when chilled air enters the branching plates 20, a turbulent flow of the air is obtained and therefore, heat dissipation is excellent.

In order to obtain best heat transfer, the bottom end of the U-shaped frame is mounted with a conductive copper plate boy 15 such that the contact face of the CPU is fully in contact and therefore high heat dissipation efficiency is obtained.

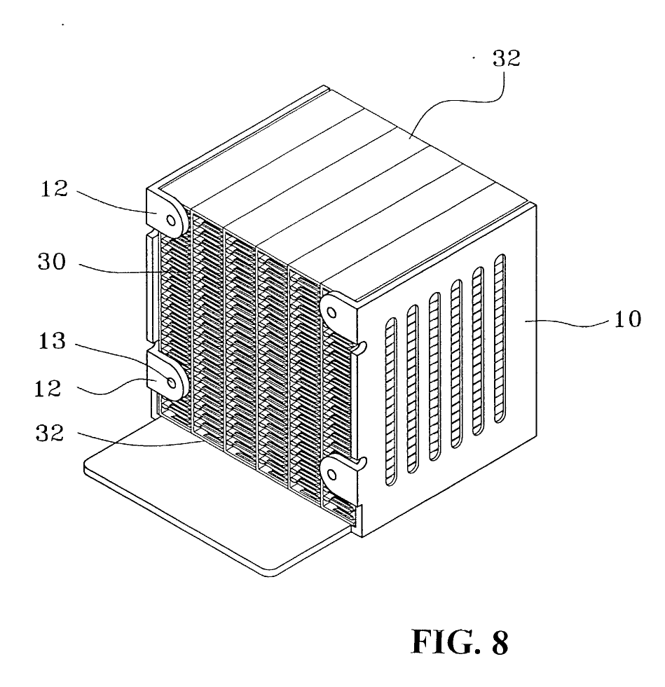

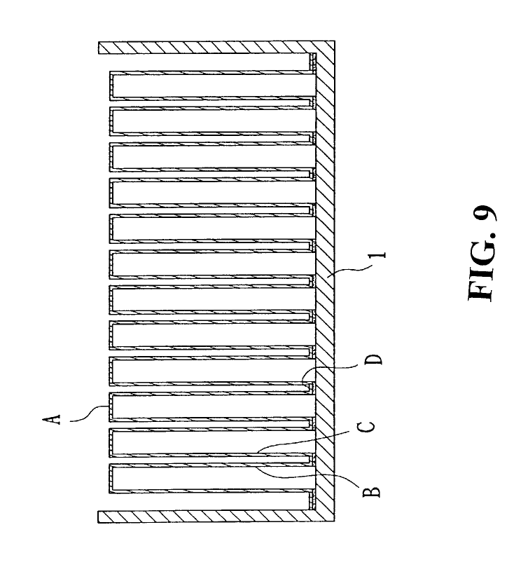

Referring to FIG. 8, there is shown another preferred embodiment in accordance with the present invention. The branching plates 20 are mounted in vertical and onto the partitioning plate 30 which is arranged in horizontal position. This provides excellent heat dissipation for high temperature CPU via the bottom end of the partitioning plate 30 which has a larger surface area in contact with the end edge 32 and rapidly conducts heat to the branching plates 20 for dissipation.

In the present preferred embodiment, the protruding plate 12 can be provided on the to end of the U-shaped frame body so that the chilled air flows downward, and the bending end 23 of the branching plate 20 is provided with conductive slot for venting.

In view of the present invention, the heat dissipation device for CPU of computer provides a larger heat dissipation surface and is applied directly onto the CPU.

It will be understood that each of the elements described above, or two or more together may also find a useful application in other types of methods differing from the type described above.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A structure of a heat dissipation device for a computer having a heat dissipation body, a plurality of metallic foil-like branching plates, a plurality of partitioning plates, characterized in that the heat dissipation body is a frame structure having an interior cavity and having a planar contacting bottom face; the foil-like branching plates are made from thin plate body with continuing bends; and each of the partitioning plates has a planar bottom face and a heat conductive contacting edge at the two lateral sides thereof; thereby the interior cavity is mounted with the partitioning plates, branching plates such that the branching plates and the partitioning plates are stacked in subsequent layers and under the downward pressing of the heat dissipation body and the heating by a high temperature furnace, each branching plates, the partitioning plates and the heat dissipation body are melted to form as a unit, providing quick dissipation of heat.

2. The structure of heat dissipation device of claim 1, further comprising a covering plate such that the covering plate urges the lateral edge of the branching plate to provide an equilibrium contacting pressure.

3. The structure of heat dissipation device of claim 2, wherein the covering plate is provided with venting holes.

4. The structure of heat dissipation device of claim 1, wherein the heat dissipation device is a U-shaped frame body and the two lateral end terminals extended from the U-shaped body are provided with engaging slots for the engaging with the covering plate.

5. The structure of heat dissipation device of claim 1, wherein the heat dissipation body is provided with protruding plates having screw holes for the mounting of a venting fan.

6. The structure of heat dissipation device of claim 1, wherein the branching plate is provided with conductive slots arranged alternately in a positive and reverse sloping direction.

7. The structure of heat dissipation device of claim 1, wherein the bottom end of the U-shaped frame of the heat dissipation body is further mounted with a heat conductive aluminum plate or a copper plate.

8. The structure of heat dissipation device of claim 1, wherein the branching plates are vertically mounted which are on the horizontal face of the partition plates, providing rapid heat transfer from the larger surface area of the lower end of the partitioning plate to the branching plates for heat dissipation.

9. The structure of heat dissipation device of claim 1, wherein the branching plate is provided with a neatly arranged conductive slots.
